(19) United States
(12) Patent Application Publication
(10) Pub. No.: US 2023/0268160 A1
(43) Pub. Date: Aug. 24, 2023

(54) ANTENNA UNIT FOR INDUCTIVELY COUPLED PLASMA, INDUCTIVELY COUPLED PLASMA PROCESSING APPARATUS AND METHOD THEREFOR

(71) Applicant: TOKYO ELECTRON LIMITED, Tokyo (JP)

(72) Inventors: Toshihiro TOJO, Nirasaki City (JP); Ryo SATO, Nirasaki City (JP)

(21) Appl. No.: 18/142,066

(22) Filed: May 2, 2023

Related U.S. Application Data
(62) Division of application No. 13/758,622, filed on Feb. 4, 2013, now abandoned.

(30) Foreign Application Priority Data
Feb. 7, 2012 (JP) 2012-024312

(51) Int. Cl. H01J 37/32; H05H 1/46

(52) U.S. Cl. CPC H01J 37/321; H05H 1/46; H01J 37/3211; H05H 1/4652

(57) ABSTRACT

An antenna unit for inductively coupled plasma includes an antenna configured to generate an inductively coupled plasma used in processing a substrate within a processing chamber of a plasma processing apparatus, wherein the antenna includes planar sections which are formed to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern.

### CROSS-REFERENCE TO RELATED APPLICATION

This application claims the benefit of Japanese Patent Application No. 2012-024312, filed on Feb. 7, 2012, in the Japan Patent Office, the disclosure of which is incorporated herein in its entirety by reference.

### TECHNICAL FIELD

The present disclosure relates to an antenna unit for an inductively coupled plasma, which is used in performing an inductively coupled plasma processing on a substrate to be processed such as a glass substrate for a flat panel display (FPD), and an inductively coupled plasma processing apparatus using the same and method therefor.

### BACKGROUND

In a process of manufacturing a flat panel display (FPD) such as a liquid crystal display (LCD), there is a step of performing a plasma processing such as a plasma etching process or a film-formation process on a glass substrate. Such a plasma processing requires various apparatuses including a plasma etching apparatus, a plasma chemical vapor deposition (CVD) apparatus or the like. In the conventional art, a capacitively coupled plasma processing apparatus has been frequently used as the plasma processing apparatus. Incidentally, in recent years, attention is concentrated on an inductively coupled plasma (ICP) processing apparatus which is capable of obtaining a high density plasma at a high vacuum level.

In the inductively coupled plasma processing apparatus, a high frequency antenna is disposed on an upper side of a dielectric wall which constitutes a top wall of a processing vessel in which a substrate to be processed is received. A process gas is fed into the processing vessel and a high frequency power is supplied to the high frequency antenna. This generates inductively coupled plasmas within the processing vessel so that the inductively coupled plasma processing apparatus performs a predetermined plasma processing on the substrate to be processed. A ring-like antenna in a spiral pattern is frequently used as the high frequency antenna.

In the inductively coupled plasma processing apparatus using the planar ring-like antenna, plasma is generated by an induction electric field, which is generated in a space formed underneath the planar antenna within the processing vessel. At this time, a distribution having high and low plasma density regions according to electric field strengths at each position underneath the planar antenna is formed. As such, a pattern shape of the planar ring-like antenna becomes an important factor in determining a plasma density distribution. For this reason, a density of the planar ring-like antenna is adjusted to make the induction electric field uniform and generate a uniform plasma.

There has been proposed a technique in which an antenna unit including two ring-like antennas in a spiral pattern which are constructed as inner and outer portions spaced apart by a certain distance in a diameter direction. Current values of the two ring-like antennas are independently controlled by adjusting their impedances so that the overlapping portion of the density distribution that is formed by diffusion of plasmas generated by each of the two ring-like antennas is controlled, thereby controlling the whole density distribution of the inductively coupled plasma. Also, there has been proposed another technique in which three or more ring-like antennas in a spiral pattern are disposed in a concentric circular pattern to obtain a uniform plasma distribution for a large-sized substrate.

In addition in recent years, an attempt has been made to perform a more fine-grained plasma control on the large-sized substrate, which includes segmentalizing a plasma control area, disposing a plurality of antennas in a planar and spiral pattern corresponding to the segmentalized plasma control areas, and controlling currents of the antennas.

However, when the plurality of antennas are disposed in a planar and spiral pattern, induction electric fields between adjacent antennas are directed the opposite direction from each other. In such space, the electric fields are annihilated each other so that the space becomes a region where no plasma is generated

### SUMMARY

The present disclosure provides an antenna unit which are capable of securing enhanced plasma controllability when a plurality of antennas are disposed to be adjacent to each other in a plane, an inductively coupled plasma processing apparatus, and an inductively coupled plasma processing method using the same.

According to one embodiment of the present disclosure, provided is an antenna unit for inductively coupled plasma, including an antenna configured to generate an inductively coupled plasma used in processing a substrate within a processing chamber of a plasma processing apparatus, wherein the antenna includes planar sections which are formed to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern.

According to another embodiment of the present disclosure, provided is an inductively coupled plasma processing apparatus for performing an inductively coupled plasma processing on a substrate, including a processing vessel, a dielectric wall configured to partition the processing vessel to form a processing chamber in which the substrate is processed in the processing vessel, the dielectric wall constituting a ceiling wall of the processing chamber, a mounting table on which the substrate is mounted and installed in the processing chamber, an antenna unit disposed above the dielectric wall and including an antenna configured to generate an inductively coupled plasma within the processing chamber, and a high frequency power supply unit configured to supply a high frequency power to the antenna, wherein the antenna includes planar sections which are formed to face a top surface of the dielectric wall and to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern.

According to yet another embodiment of the present disclosure, provided is an inductively coupled plasma processing apparatus for performing an inductively coupled plasma processing on a substrate, including a processing vessel, a metal wall configured to partition the processing vessel to form a processing chamber in which the substrate is processed in the processing vessel, the metal wall constituting a ceiling wall of the processing chamber and being insulated from the processing vessel, a mounting table on which the substrate is mounted and installed in the processing chamber, an antenna unit disposed above the metal wall and including an antenna configured to generate an inductively coupled plasma within the processing chamber, and a high frequency power supply unit configured to supply a high frequency power to the antenna, wherein the antenna includes planar sections which are formed to face a top surface of the metal wall and to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern.

According to still another embodiment of the present disclosure, provided is a method of performing an inductively coupled plasma processing using an inductively coupled plasma processing apparatus, wherein the inductively coupled plasma processing apparatus includes: a processing chamber configured to receive the substrate therein and configured to process the substrate with plasma, a mounting table on which the substrate is mounted and installed in the processing chamber, an antenna unit including an antenna configured to generate an inductively coupled plasma within the processing chamber, and a high frequency power supply unit configured to supply a high frequency power to the antenna, wherein the antenna includes planar sections which are formed to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern, wherein the plurality of antenna segments are arranged such that the planar portions form the planar sections in a ring-like shape, wherein a current is individually flown to each of the plurality of antenna segments such that the current flows to the planar sections as a whole in the ring-like shape, the method including performing an inductively coupled plasma processing on a substrate.

According to still another embodiment of the present disclosure, provided is a method of performing an inductively coupled plasma processing using an inductively coupled plasma processing apparatus, wherein the inductively coupled plasma processing apparatus includes: a processing chamber configured to receive the substrate therein and configured to process the substrate with plasma, a mounting table on which the substrate is mounted and installed in the processing chamber, an antenna unit including an antenna configured to generate an inductively coupled plasma within the processing chamber, and a high frequency power supply unit configured to supply a high frequency power to the antenna, wherein the antenna includes planar sections which are formed to face the substrate and generate an induction electric field that contributes to generate the inductively coupled plasma, wherein a plurality of antenna segments having planar portions which form a portion of the planar sections are arranged to constitute the planar sections, wherein the antenna segments are constituted by winding an antenna line in a direction intersecting with the substrate in a longitudinal and spiral pattern, wherein the plurality of antenna segments are arranged so that the planar portions are arranged in a grid pattern or a straight pattern and the planar sections are formed in a rectangular shape, wherein a current is individually flown to each of the plurality of antenna segments in parallel and in the same direction, the method including performing an inductively coupled plasma processing on a substrate.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view of an inductively coupled plasma processing apparatus according to a first embodiment of the present disclosure.

FIG. 2 is a plane view showing an example of a high frequency antenna of an antenna unit for inductively coupled plasma, which is used in the inductively coupled plasma processing apparatus shown in FIG. 1.

FIG. 3 is a perspective view showing first antenna segments of an outer antenna of the antenna unit for inductively coupled plasma.

FIG. 4 is a perspective view showing second antenna segments of the outer antenna of the antenna unit for inductively coupled plasma.

FIG. 5 is a plane view showing a middle antenna of the antenna unit for inductively coupled plasma.

FIG. 6 is a plane view showing an inner antenna of the antenna unit for inductively coupled plasma.

FIG. 7 is a plane view showing another example of a middle antenna and an inner antenna of the antenna unit for inductively coupled plasma.

FIG. 8 is a schematic view showing a power supply part of the antenna unit for inductively coupled plasma.

FIG. 9 is a view explaining a direction of an induction electric field (high frequency current) when the conventional antenna in a spiral pattern is used as the antenna segments.

FIG. 10 is a view explaining a direction of an induction electric field when the antenna unit of the inductively coupled plasma processing apparatus according to a first embodiment of the present disclosure is used.

FIG. 11 is a view explaining an illustrative configuration of antenna segments.

FIG. 12 is a plane view showing an antenna constituting a radio frequency antenna for use in an antenna unit according to a second embodiment of the present disclosure.

FIG. 13 is a perspective view showing antenna segments of the antenna shown in FIG. 12.

FIG. 14 is a sectional view showing an inductively coupled plasma processing apparatus according to a third embodiment of the present disclosure.

FIG. 15 is a plane view explaining a structure of a metal wall shown in FIG. 14.

FIG. 16 is a view explaining a plasma generation principle in the inductively coupled plasma processing apparatus according to the third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

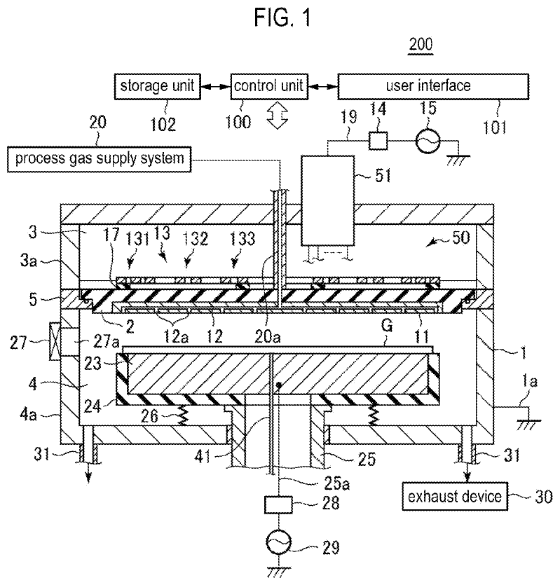

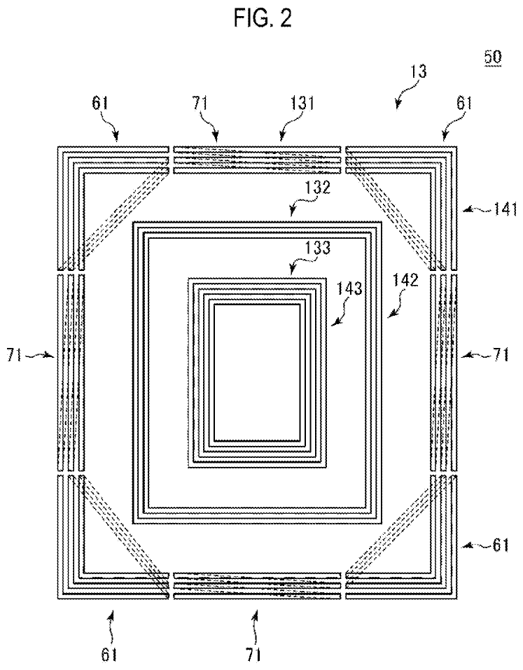

FIG. 1 shows a sectional view of an inductively coupled plasma processing apparatus 200 according to a first embodiment of the present disclosure, and FIG. 2 shows a plane view of an antenna unit to be used in the inductively coupled plasma processing apparatus 200. For example, the inductively coupled plasma processing apparatus 200 is used in etching a metal film, an ITO (Indium Tin Oxide) film, an oxide film or the like, which are used in forming a thin film transistor on a glass substrate for FPD (Flat Panel Display), or ashing a resist film. Examples of the FPD may include a liquid crystal display (LCD), an electro luminescence (EL) display, a plasma display panel (PDP) or the like.

The inductively coupled plasma processing apparatus 200 includes an airtight main body 1 having a square column shape, which is made of a conductive material, e.g., an aluminum whose inner wall surface is anodically oxidized. The main body 1 is separably assembled and is electrically grounded through a ground line 1a. The main body 1 is vertically partitioned into an antenna chamber 3 and a processing chamber 4 by a dielectric wall (dielectric window) 2 interposed therebetween. Accordingly, the dielectric wall 2 acts as a top wall of the processing chamber 4. The dielectric wall 2 is formed of a ceramic such as Al₂O₃, quartz, or the like.

A shower housing 11 for supplying the process gas is located in a lower portion of the dielectric wall 2. The shower housing 11 is formed in, e.g., a cross shape, and acts as a beam which supports the dielectric wall 2 from the bottom. The dielectric wall 2 may be divided into four sections corresponding to the shower housing 11 formed in the cross shape. Further, the shower housing 11 which supports the dielectric wall 2 is provided to be suspended to a ceiling of the main body 1 by a plurality of suspenders (not shown).

The shower housing 11 may be formed of a conductive material, e.g., a metal.

Examples of the metal may include an aluminum whose inner or outer surfaces are anodically oxidized to prevent contaminants from forming. The shower housing 11 is electrically grounded.

A horizontally extending gas channel 12 is formed in the shower housing 11. The gas channel 12 is in communication with a plurality of gas injection holes 12a which are extended downward. In addition, a gas supply tube 20a is installed to be in communication with the gas channel 12 in the center of the surface of the dielectric wall 2. The gas supply tube 20a is provided to pass through a ceiling of the main body 1 outward, and is connected to a process gas supply system 20 which is equipped with a process gas supply source, a valve system and the like. With this configuration, in the plasma process, the process gas supplied from the process gas supply system 20 is supplied into the shower housing 11 through the gas supply tube 20a, and subsequently, is injected from the gas injection holes 12a into the processing chamber 4.

An internally-extended supporting bracket 5 is installed between a sidewall 3a of the antenna chamber 3 and a sidewall 4a of the processing chamber 4 in the main body 1. The dielectric wall 2 is mounted on the supporting bracket 5.

An antenna unit 50 including a high frequency (RF) antenna 13 is installed within the antenna chamber 3. The high frequency antenna 13 is connected to a high frequency power supply 15 through a power supply part 51, a power supply line 19 and a matching unit 14. Further, the high frequency antenna 13 is spaced apart from the dielectric wall 2 by spacers 17 made of an insulation member. A high frequency power of, e.g., 13.56 MHz, which is generated from the high frequency power supply 15, is supplied to the high frequency antenna 13 so that an induction electric field is generated within the processing chamber 4. The induction electric field changes the process gas supplied from the shower housing 11 into the plasma. The antenna unit 50 and the power supply part 51 will be described later.

A mounting table 23, which mounts a rectangular glass substrate for FPD (hereinafter simply referred to as “substrate”) G thereon, is installed in a lower portion inside the processing chamber 4 to face the high frequency antenna 13 with the dielectric wall 2 being interposed therebetween. The mounting table 23 is formed of a conductive material, e.g., an aluminum having an anodically-oxidized surface. The substrate G mounted on the mounting table 23 is adsorbed by an electrostatic chuck (not shown).

The mounting table 23 is received in an insulating frame 24 and is supported by a hollow support column 25. The support column 25 passes through the bottom portion of the main body 1 while maintaining an airtight condition and is supported by an elevating mechanism (not shown) which is disposed outside the main body 1. The support column 25 is vertically driven by the elevating mechanism when the substrate G is carried into and out of the processing chamber 4. A bellows 26 which air-tightly enclosures the support column 25 is installed between the insulating frame 24 receiving the mounting table 23 therein and the bottom portion of the main body 1. By this configuration, the airtightness within the processing chamber 4 is assured even when the mounting table 23 moves upward and downward. Further, in the sidewall 4a of the processing chamber 4, a transfer gate 27a through which the substrate G is transferred and a gate valve 27 configured to open/close the transfer gate 27a are provided.

The mounting table 23 is connected to a high frequency power supply 29 through a matching unit 28 by a power supply line 25a disposed inside the hollow support column 25. The high frequency power supply 29 applies high frequency power for bias having frequency of, e.g., 6 MHz, during a plasma process to the mounting table 23. A self-bias generated by the high frequency power for bias allows ions in the plasma generated within the processing chamber 4 to be efficiently attracted to the substrate G.

Further, a temperature control mechanism constructed by a heating means such as a ceramic heater, a coolant channel and the like, and a temperature sensor, are provided inside the mounting table 23 to control temperature of the substrate G, wherein these parts are not shown in drawings. Pipes or lines for such mechanisms and parts are led out of the main body 1 through the hollow support column 25.

The bottom portion of the processing chamber 4 is connected to an exhaust device 30 including a vacuum pump or the like through an exhaust pipe 31. The exhaust device 30 exhausts the processing chamber 4 so that the processing chamber 4 is set and maintained at a predetermined vacuum atmosphere (e.g., 1.33 Pa) during the plasma process.

A cooling space (not shown) is formed in a rear side of the substrate G mounted on the mounting table 23. A He gas channel 41 for supplying a He gas as a heat conductive gas having a constant pressure to the cooling space is formed in the rear side of the substrate G. The supply of the heat conductive gas to the rear side of the substrate G prevents the temperature of the substrate G from being elevated or changed under a vacuum condition.

The above-mentioned respective components of the plasma processing apparatus 200 are connected to and controlled by a control unit 100 including a microprocessor (or a computer). The control unit 100 is connected with a keyboard for allowing an operator to manipulate inputs such as a command input and so on to manage the plasma processing apparatus 200, and a user interface 101 composed of a display or the like for visualizing and displaying the running status of the plasma processing apparatus 200. The control unit 100 is also connected to a storage unit 102 storing control programs for realizing various processes to be executed in the plasma processing apparatus 200 under control of the control unit 100, and programs, i.e., process recipes, for causing various components of the plasma processing apparatus 200 to perform their respective processes depending on their respective processing conditions. The process recipes are stored in a storage medium of the storage unit 102. Examples of the storage medium used may include a hard disk or a semiconductor memory contained in the computer, or a transferable (or portable) memory such as a CD-ROM, DVD, flash memory or the like. Alternatively, the recipes may be appropriately transmitted from other external apparatuses via their respective dedicated lines. If necessary, any process recipe may be called from the storage unit 102 according to an instruction from the user interface 101 and then executed by the control unit 100 so that a desired process can be performed in the plasma processing apparatus 200 under control of the control unit 100.

Now, the antenna unit 50 will be described in detail. As described above, the antenna unit 50 includes the high frequency antenna 13, and the power supply part 51 configured to supply the high frequency power processed by the matching unit 14 to the high frequency antenna 13.

As shown in FIG. 2, the high frequency antenna 13 includes an outer antenna 131, a middle antenna 132 and an inner antenna 133. Each of these antennas 131, 132 and 133 has a planar region where an induction electric field that contributes to generate plasma is generated, specifically, planar frame-like regions 141, 142 and 143, respectively. These frame-like regions 141, 142 and 143 are formed to face the dielectric wall 2 at the opposite side of the substrate G. Further, the frame-like regions 141, 142 and 143 are concentrically aligned with each other, and constitute a rectangular planar corresponding to the rectangular substrate G as a whole.

The outer antenna 131 is composed of a total of eight antenna segments, i.e., four first antenna segments 61 constituting the corner portions of the frame-like region 141, and four second antenna segments 71 constituting a center portion of each side of the frame-like region 141 so that the outer antenna 131 is constituted as a multi-divisional ring-like antenna as a whole.

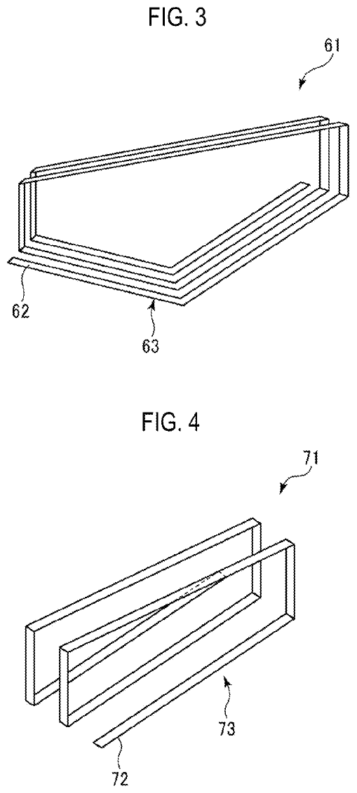

As shown in FIG. 3, each of the first antenna segments 61 is constituted by winding an antenna line 62 made of a conductive material, e.g., copper, in a direction intersecting with the substrate G (the dielectric wall 2) in a longitudinal and spiral pattern. Planar sections 63 facing the dielectric wall 2 constitute portions (corner portions) of the frame-like region 141 configured to generate the induction electric field that contributes to generate plasma. In one embodiment, the planar sections 63 are disposed so that the antenna line 62 is disposed to form three parallel corner portions.

As shown in FIG. 4, each of the second antenna segments 71 is constituted by winding an antenna line 72 made of a conductive material, e.g., copper, in a direction intersecting with the substrate G (the dielectric wall 2) in a longitudinal and spiral pattern. Planar sections 73 facing the dielectric wall 2 constitute portions (center portion of each side) of the frame-like region 141 which generates the induction electric field that contributes to generate plasma. In one embodiment, the planar sections 73 are disposed so that the antenna line 72 is disposed to form three parallel portions.

Both of the middle antenna 132 and the inner antenna 133 are constituted as a planar antenna in a spiral pattern (which are shown in a concentric circular pattern in FIG. 2, for the sake of simplicity). The whole planes of the middle and inner antennas 132 and 133 which face the dielectric wall 2 constitute the frame-like regions 142 and 143, respectively.

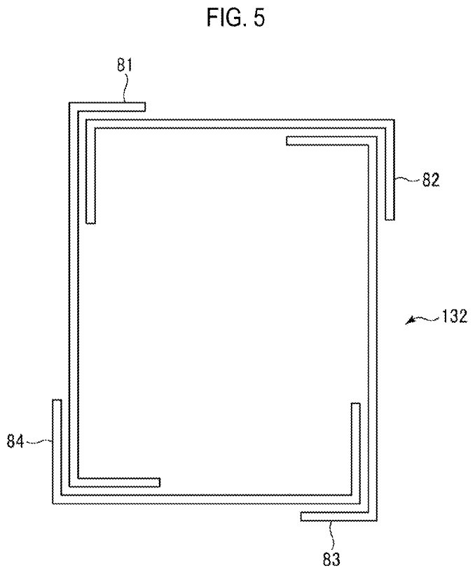

For example, as shown in FIG. 5, the middle antenna 132 constitutes a multi-antenna (e.g., quadruple antenna) in a spiral pattern which is formed by winding four antenna lines 81, 82, 83 and 84 made of a conductive material, e.g., copper. Specifically, the antenna lines 81, 82, 83 and 84 are wound to be displaced from each other by 90 degrees such that the number of turns of a corner portion where the plasma tends to be weaker is larger than that of the center portion of each side. As shown in FIG. 5, as one example, the number of turns of the corner portion is 2 and the number of turns of the center portion of each side is 1. A region where the antenna lines 81, 82, 83 and 84 are disposed constitutes the frame-like region 142.

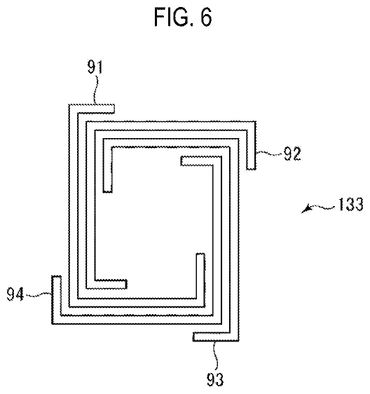

For example, as shown in FIG. 6, the inner antenna 133 constitutes a multi-antenna (e.g., quadruple antenna) in a spiral pattern which is formed by winding four antenna lines 91, 92, 93 and 94 made of a conductive material, e.g., copper. Specifically, the antenna lines 91, 92, 93 and 94 are wound to be displaced from each other by 90 degrees such that the number of turns of a corner portion where the plasma tends to be weaker is larger than that of the center portion of each side. As shown in FIG. 6, as one example, the number of turns of the corner portion is 3 and the number of turns of the center portion of each side is 2. A region where the antenna lines 91, 92, 93 and 94 are disposed constitutes the frame-like region 143.

In the case where the middle antenna 132 and the inner antenna 133 are constituted by the multiple antennas, the number of the antenna lines of each of the middle and inner antennas 132 and 133 is not limited to four. In some embodiments, the multiple antennas having an arbitrary number of antenna lines may be used, and also the displacement angle is not limited to 90 degrees.

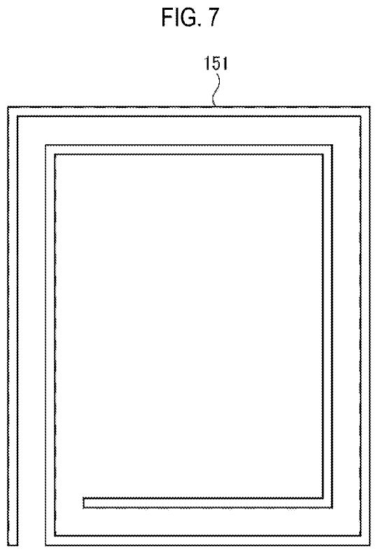

In some embodiments, as shown in FIG. 7, the middle antenna 132 and the inner antenna 133 may be formed by winding a single antenna line 151 in a spiral pattern.

Further still, in some embodiments, the number of the aforementioned ring-like antennas is not limited to three. For example, two ring-like antennas or more than three ring-like antennas may be used. That is, in some embodiments, a structure formed by one or more single ring-like antenna in addition to the ring-like antenna having a structure obtained by arranging the antenna segments in a ring-like shape may be employed.

Further, in some embodiments, the high frequency antenna 13 may be constituted by only one or more multi-divisional ring-like antenna having a structure formed by arranging antenna segments in a ring-like shape, which is similar to the outer antenna 131.

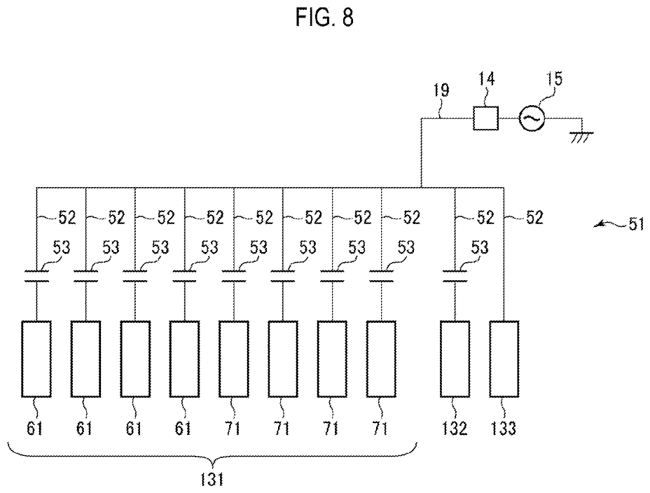

As shown in FIG. 8, the power supply part 51 includes ten branch lines 52 branched from the power supply line 19, the branch lines 52 being connected to eight antenna segments (the four first antenna segments 61 and the four second antenna segments 71) of the outer antenna 131, the middle antenna 132 and the inner antenna 133. A variable condenser 53 used as an impedance control unit is installed in each of the branch lines 52 excluding one branch line 52. In FIG. 8, the variable condenser 53 is not installed in only the branch line 52 connected to the inner antenna 133. Accordingly, a total of nine variable condensers 53 are installed. The branch lines 52 are connected to power supply terminals (not shown) which are formed in end portions of the eight antenna segments of the outer antenna 131, the middle antenna 132 and the inner antenna 133, respectively.

Combinations of each of the eight antenna segments of the outer antenna 131 and the middle antenna 132, and each of the variable condensers 53 connected thereto constitute antenna circuits, respectively; and the inner antenna 133 constitutes one antenna circuit by itself. An impedance of each of the antenna circuits which includes the eight antenna segments of the outer antenna 131 and the middle antenna 132, is controlled by adjusting a capacity of each of the nine variable condensers 53. With this configuration, it is possible to control current to flow into each of the antenna circuits which includes the eight antenna segments of the outer antenna 131, the middle antenna 132 and the inner antenna 133. In this way, the control of the current to be flown to each of the antenna circuits controls an induction electric field in a plasma control area which corresponds to each of the antenna circuits, which makes it possible to sensitively control a plasma density distribution. Alternatively, the variable condensers 53 may be installed in all the antenna circuits.

In some embodiments, a current to be flown to the outer antenna 131 may be controlled for every antenna segments. Alternatively, the antenna segments may be divided on a group basis and a current to be flown to the outer antenna 131 may be controlled on the group basis.

The control of current as described above may be similarly performed in second and third embodiments, which will be described later.

Hereinafter, an operation of performing a plasma process, for example, a plasma etching process on the substrate G using the inductively coupled plasma processing apparatus 200 configured as above, will be described.

First, the substrate G is carried into the processing chamber 4 through the transfer gate 27a by a transfer mechanism (not shown) with the gate valve 27 opened. Subsequently, the substrate G is mounted on the mounting table 23 and is fixed on the mounting table 23 by an electrostatic chuck (not shown). Thereafter, the process gas supplied from the process gas supply system 20 is injected into the processing chamber 4 through the gas injection holes 12a of the shower housing 11, and simultaneously, the interior of the processing chamber 4 is exhausted through the exhaust pipe 31 by the exhaust device 30. Then, the interior of the processing chamber 4 is maintained at a pressure atmosphere of about 0.66 to 26.6 Pa.

At this time, the He gas as a heat conductive gas is fed to the cooling space formed in the rear side of the substrate G so as to prevent the temperature of the substrate G from being increased or changed.

Subsequently, a high frequency of, e.g., 13.56 MHz, is applied to the high frequency antenna 13 from the high frequency power supply 15. The high frequency is transferred to the dielectric wall 2, thus generating a uniform induction electric field within the processing chamber 4. The induction electric field generated as above allows the process gas to be changed into plasma within the processing chamber 4, thereby generating high density inductively coupled plasma. By such plasma, the substrate G is subjected to the plasma process, e.g., the plasma etching process.

In this case, as described above, the high frequency antenna 13 is constituted by forming the outer antenna 131, the middle antenna 132 and the inner antenna 133, which are the ring-like antenna, in a concentric circular pattern, and the outer antenna 131 is constituted by the total of eight antenna segments which include the four first antenna segments 61 constituting the corner portions and the four second antenna segments 71 constituting the center portions of the sides, in the frame-like region 141 where the induction electric field that contributes to generate plasma is generated. With this configuration, it is possible to control the induction electric field of the plasma control area corresponding to the antenna segments, thus sensitively controlling the plasma density distribution.

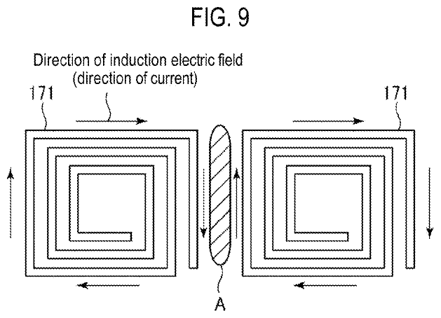

However, if the first antenna segments 61 and the second antenna segments 71 constituting the outer antenna 131 are constituted as the spiral antenna formed by winding the antenna lines in a planar pattern, which has been used as the conventional antenna, a direction of an induction electric field (high frequency current) in an adjacent antenna 171 in spiral pattern is sometimes inverted, as shown in FIG. 9. In such case, the induction electric fields are annihilated each other, thereby making an induction electric field formed in a region A formed between respective antennas 171 in a spiral pattern extremely to be weakened, such that the region A becomes a region where no plasma is substantially generated.

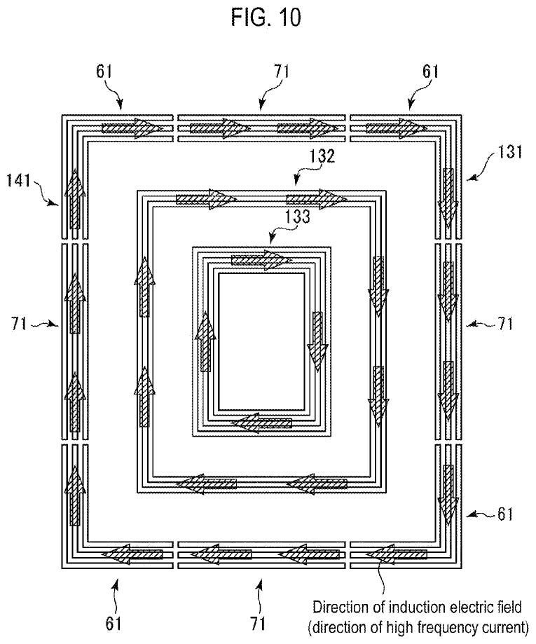

Meanwhile, in this embodiment, the first antenna segments 61 and the second antenna segments 71 are formed by winding the antenna line 62 and the antenna line 72 in the direction intersecting with the substrate G (the dielectric wall 2) in a longitudinal and spiral pattern, respectively. As such, as shown in FIG. 10, directions of induction electric fields (radio frequency currents) formed in the planar sections 63 and 73 (which are portions where the induction electric field that contributes to generate plasma is generated) facing the dielectric wall 2 are biased in the same direction along the frame-like region 141. Accordingly, there is no a region where the induction electric fields are annihilated each other. This increases an efficiency of the antenna unit compared with the case where the spiral antennas are arranged in a planar pattern, and enhances a uniformity of plasma. Further, since directions of induction electric fields formed in the middle antenna 132 and the inner antenna 133 are equal to that of the outer antenna 131, there is no a region where the induction electric fields are annihilated each other, even for an inner region.

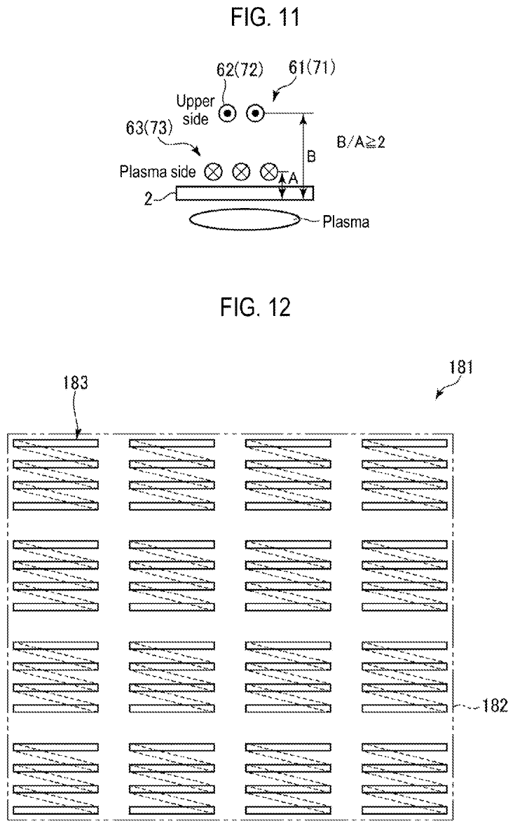

In some embodiments, as schematically shown in FIG. 11, in order to prevent an induction electric field formed in a portion of the first antenna segments 61 and the second antenna segments 71 disposed in a space formed at a side opposed to the planar sections 63 and 73 of the antenna lines 62 and 72 from contributing to generate plasma, a distance B to the plasma from the portion may preferably be set to be twice or more larger than a distance A to the plasma from the antenna lines 62 and 72 of the planar sections 63 and 73.

### Second Embodiment

Now, a second embodiment of the present disclosure will be described.

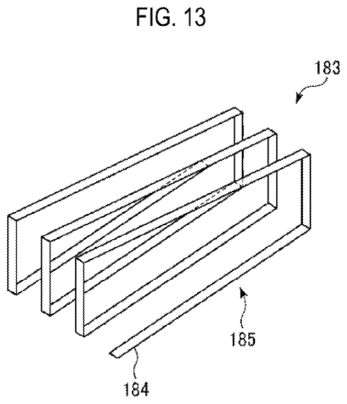

FIG. 12 is a plane view showing an antenna constituting a radio frequency antenna for use in an antenna unit according to the second embodiment of the present disclosure.

In the aforementioned first embodiment, the example is described in which the outer antenna 131 is constituted as the multi-divisional ring-like antenna in which the plurality of antenna segments in a longitudinal and spiral pattern are disposed in a ring-like shape such that lower portions of the antenna segments form the frame-like region 141 where the induction electric field that contributes to generate plasma is generated, and also, the antenna unit 50 including the high frequency antenna 13 that is constituted by arranging the middle antenna 132 and the inner antenna 133 as an ring-like antenna in a concentric circular pattern is used. Meanwhile, in the second embodiment, as shown in FIG. 12, the high frequency antenna 13 is constituted by only a parallel antenna 181. Specifically, the parallel antenna 181 includes a rectangular planar region 182 which is configured to generate an induction electric field that contributes to generate plasma and is formed to face the substrate G while facing the dielectric wall 2. The rectangular planar region 182 is divided into a plurality of grid-like plasma control sectors. Antenna segments 183 constituting a portion of the rectangular planar region 182 are disposed in the plasma control sectors, respectively. The parallel antenna 181 is constituted as a multi-divisional parallel antenna where all antenna lines are arranged in parallel in the rectangular planar region 182.

As shown in FIG. 13, the antenna segments 183 is constituted by winding an antenna line 184 made of a conductive material, e.g., copper, in a direction intersecting with the substrate G (the dielectric wall 2), e.g., a direction perpendicular to the substrate G, i.e., a vertical direction in a spiral pattern. A planar section 185 facing the dielectric wall 2 constitutes a portion of the rectangular planar region 182 where an induction electric field that contributes to generate plasma is generated. In this embodiment, four antenna lines 184 are arranged in parallel to form the planar section 185.

While in FIG. 12, the antenna segments 183 have been illustrated to be arranged as a 4×4 matrix, i.e., 16-division type, the present disclosure is not limited thereto. For example, the antenna segments 183 may be arranged as a 2×2 matrix (i.e., 4-division type), a 3×3 matrix (i.e., 9-division type), a 5×5 matrix (15-division type), or more matrix. By such configuration, meshes of the grid are minutely formed, which increases the plasma control area, thus more finely performing the plasma control.

As described above, the planar sections 185 of the antenna segments 183 are arranged in the grid pattern as shown in FIG. 12 such that directions of induction electric fields (high frequency currents) of the antenna segments 183 become equal to each other. As a result, there is no a region where the induction electric fields are annihilated each other as illustrated in the conventional example in which the spiral antenna is arranged. Therefore, it is possible to increase efficiency of the antenna unit, and further enhance uniformity of plasma compared with the conventional example.

While in the above embodiment, the parallel antenna 181 has been described to be constituted by arranging the antenna segments 183 in the grid pattern, the present disclosure is not limited thereto. For example, the parallel antenna 181 may be constituted by arranging the antenna segments 183 in a simple straight pattern.

### Third Embodiment

Now, a third embodiment of the present disclosure will be described.

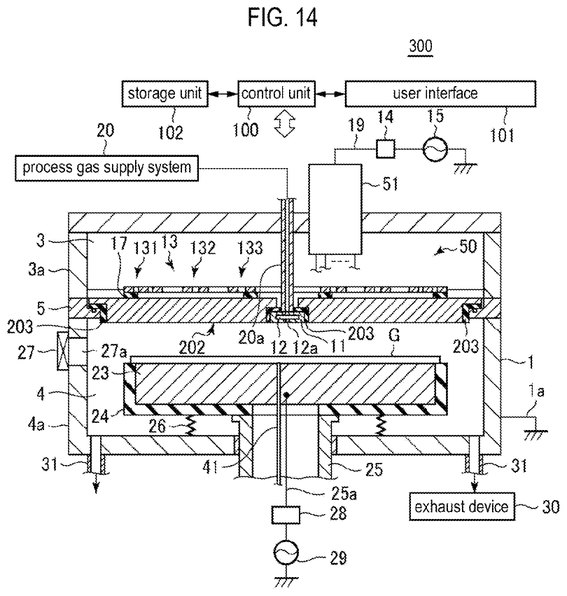

FIG. 14 is a sectional view showing an inductively coupled plasma processing apparatus 300 according to the third embodiment of the present disclosure.

In the third embodiment, instead of the dielectric wall 2 (or the dielectric window) of the inductively coupled plasma processing apparatus 200 according to the first embodiment, a metal wall (or metal window) 202 made of a nonmagnetic metal, e.g., aluminum (Al) or an alloy including Al is provided. The other configuration is basically same as in the first embodiment. Accordingly, in FIG. 14, the same reference numerals indicate same or similar elements shown in FIG. 1, and a further description thereof is omitted herein.

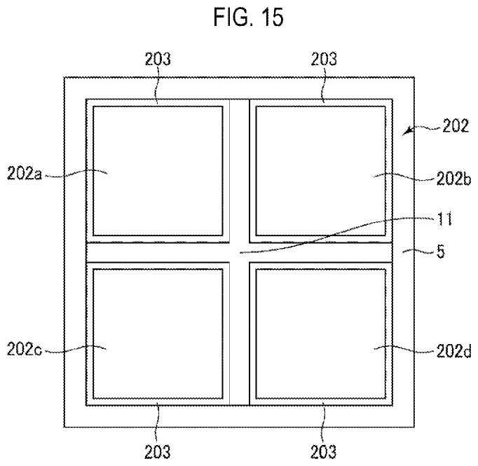

In the third embodiment, the metal wall 202 is divided in a grid pattern. Specifically, as shown in FIG. 15, the metal wall 202 is divided into four division walls 202a, 202b, 202c and 202d. These division walls 202a, 202b, 202c and 202d are mounted on the shower housing 11 acting as the support beam and the supporting bracket 5 with respective insulation members 203 interposed between the division walls 202a, 202b, 202c and 202d and the shower housing 11 and the supporting bracket 5, respectively. With this configuration, the four division walls 202a, 202b, 202c and 202d are insulated from the supporting bracket 5, the shower housing 11 and main body 1, and further the division walls 202a, 202b, 202c and 202d are insulated from each other.

Although the dielectric wall 2 used in the first embodiment is formed of a brittle material, e.g., quartz, the metal wall 202 used in this embodiment is formed of a ductile material. Therefore, it is possible to easily increase the size of the metal wall 202 when manufacturing and easily meet the demand for the large-sized substrate.

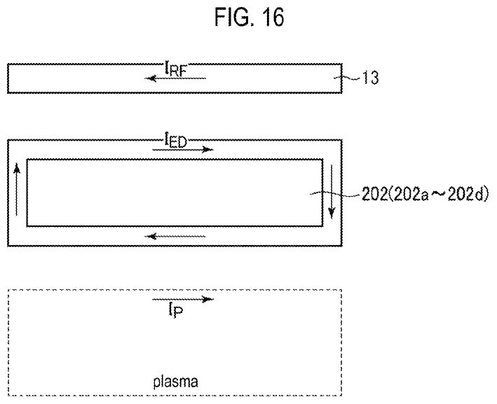

In use of the metal wall 202, a plasma generation principle is different from the case where the dielectric wall 2 is used. Specifically, as shown in FIG. 16, an induced current is generated in the top surface (surface of the high frequency antenna side) of the metal wall 202 by a high frequency current I_{RF} flowing along the high frequency antenna 13 in a ring-like shape. The induced current flows along only the surface of the metal wall 202 by a skin effect. However, since the metal wall 202 is divided into the four division walls 202a, 202b, 202c and 202d, which are insulated from the supporting bracket 5, the shower housing 11 acting as the support beam, and the main body 1, the induced currents flown along the top surface of the metal wall 202, i.e., the division walls 202a, 202b, 202c and 202d, flow along side surfaces of the division walls 202a, 202b, 202c and 202d, respectively, and subsequently, flow along lower surfaces (the surface of the processing chamber 4 side) of the division walls 202a, 202b, 202c and 202d. Further, the induced currents return to the top surface of the metal wall 202 through the side surfaces of the division walls 202a, 202b, 202c and 202d, thereby generating eddy currents I_{ED}. By this manner, the eddy currents I_{ED} which loop from the top surfaces (surfaces of high frequency antenna 13 side) of the division walls 202a, 202b, 202c and 202d to the lower surfaces (the surface of the processing chamber 4 side) are generated in the metal wall 202. Among the looping eddy currents I_{ED}, one flowing along the lower surface of the metal wall 202 allows an induction electric field to be generated within the processing chamber 4, which generates plasma of process gas.

Used as the high frequency antenna 13 may be one obtained by forming the outer antenna 131, the middle antenna 132 and the inner antenna 133 being the ring-like antenna in a concentric circular pattern as shown in FIG. 2, one constituted by only a ring-like antenna having a structure obtained by arranging antenna segments in a ring-like shape, and one having only the straight parallel antenna 181 constituted by arranging the straight-like antenna segments 183 in the same direction as shown in FIG. 12.

In the case where the high frequency antenna is constituted by the ring-like antenna, when one sheet of the metal wall 202 is used, the eddy currents I_{ED} which are generated in the top surface of the metal wall 202 by the high frequency antenna merely loop along the top surface of the metal wall 202. Accordingly, the eddy currents I_{ED} do not flow along the lower surface of the metal wall 202, which prevents the plasma from being generated. Therefore, as described above, the metal wall 202 is divided into the plurality of division walls which are insulated from each other, such that the eddy currents I_{ED} flow along the lower surface of the metal wall 202.

Further, when the high frequency antenna is constituted as the parallel antenna 181 as shown in FIG. 12, even for one sheet of the metal wall 202, the eddy current I_{ED} generated on the top surface of the metal wall 202 allows a loop current which flows from the top surface to the lower surface along the side surface, and subsequently, returns to the surface through the side surface, to be generated. This generates the induction electric field in the lower surface of the metal wall 202, thereby generating plasma. That is, an antenna current corresponding to one sheet of the metal wall may flow to traverse without closing in a loop pattern in the top surface, irrespective of using the plural-divided metal walls or one sheet of the metal wall.

Moreover, the present disclosure is not limited to the above embodiments but may be modified variously. For example, while in the above embodiments, the plurality of antenna segments in a longitudinal and spiral pattern has been exemplified as being arranged in the ring-like shape and in the straight pattern (matrix pattern), the present disclosure is not limited thereto. In some embodiments, the plurality of antenna segments may be arranged in an arbitrary pattern in response to plasma to be generated. Further, as described above, the high frequency antenna may be constituted by only the antenna formed by arranging the plurality of antenna segments in a longitudinal and spiral pattern, and may be constituted by combining the antenna formed by arranging the plurality of antenna segments in a longitudinal and spiral pattern and another antenna.

Further, while in the above embodiments, the variable condensers have been described to be used as the impedance control unit configured to control current of each of the antenna segments or the antenna, the present disclosure is not limited thereto. For example, another impedance control unit such as a variable coil may be used. Further, in some embodiments, the current may be distributed using a power splitter so as to control current of each antenna segment or antenna. Further, high frequency power supply sources may be installed corresponding to each of the antenna segments or the antenna such that current of each of the antenna segments or the antenna is controlled.

Moreover, while in the above embodiments, the ceiling portion of the processing chamber has been described to be constituted by the dielectric wall or the metal wall, and the antenna has been described to be arranged along the dielectric wall of the ceiling portion positioned outside the processing chamber or the top surface of the metal wall, the present disclosure is not limited thereto. For example, in some embodiments, an antenna having a structure in which the antenna and the plasma generation region can be separated by the dielectric wall or the metal wall, may be arranged within the processing chamber.

Moreover, in the above embodiments, the present disclosure has been described to be applied to the etching process, but may be applied to another plasma processing apparatus such as a chemical vapor deposition (CVD) film-formation apparatus. Further, while in the above embodiments, the rectangular substrate for FPD has been exemplified as being used as the substrate, another rectangular substrate such as a solar cell may be used. Further, while the present disclosure is not limited to the rectangular substrate, for example, a circular substrate such as a semiconductor wafer may be used.

According to the present disclosure, the antenna includes planar sections which are formed to face the substrate and generate the induction electric field that contributes to generate the inductively coupled plasma. Further, a plurality of antenna segments having planar portions which form a portion of the planar sections are arranged. The antenna segments are constituted by winding the antenna line in a direction intersecting with the substrate in a longitudinal and spiral pattern. With this configuration, it is possible to arrange the antenna segments while preventing the direction of the induction electric field from being inverted between adjacent antenna segments in the planar sections, thus preventing the region where the induction electric fields are annihilated each other from being generated. Therefore, it is possible to increase efficiency of the antenna unit, and enhance uniformity of plasma.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1-15. (canceled)

16. An antenna unit for inductively coupled plasma, comprising:
an antenna configured to generate an inductively coupled plasma used in processing a substrate within a processing chamber of a plasma processing apparatus,
wherein the antenna includes planar sections which are formed to face the substrate and generate an induction electric field that contributes to generate the inductively coupled plasma,
wherein a plurality of antenna segments having planar portions which form a portion of the planar sections are arranged to constitute the planar sections,
wherein the antenna segments are constituted by winding an antenna line in a direction intersecting with the substrate in a longitudinal and spiral pattern,
wherein the plurality of antenna segments are arranged so that the planar portions are arranged in a grid pattern or a straight pattern,
wherein the planar sections are formed in a rectangular shape, and
wherein the plurality of antenna segments constitute a multi-divisional parallel antenna in which the antenna line is disposed in parallel.

17. The antenna unit of claim 16, wherein a high frequency power is supplied to the antenna so that a current is individually flown to each of the plurality of antenna segments in parallel and in a same direction.
